(19) United States
(12) Patent Application Publication
(10) Pub. No.: US 2012/0115083 A1
(43) Pub. Date: May 10, 2012

(54) Biodegradable Film for Flexographic Printing Plate Manufacture and Method of Using the Same

(76) Inventor: Ryan W. Vest, Cumming, GA (US)

(21) Appl. No.: 12/939,388

(22) Filed: Nov. 4, 2010

(51) Int. Cl. G03F 7/004; G03F 7/26

(52) U.S. Cl. 430/273.1; 430/270.1; 430/306

(57) ABSTRACT

The use of biodegradable polymer films in the manufacture of photosensitive relief image printing plates is described, including printing plates produced from liquid photopolymer resins and from sheet polymers as well as direct write/laser engravable printing plates. The biodegradable polymer films can be used as substrate layers, oxygen barrier layers, and coverfilms and, once the printing plates have been used and disposed of, the biodegradable polymer films are capable of decomposing in the environment.

### FIELD OF THE INVENTION

The present invention relates generally to a biodegradable or compostable film for use in the manufacture of relief image printing plates.

### BACKGROUND OF THE INVENTION

Flexographic printing is widely used in the production of newspapers and in the decorative printing of packaging media. Numerous photosensitive printing plate formulations have been developed to meet the demand for fast, inexpensive processing and long press runs.

Photosensitive printing elements used for making flexographic relief image printing plates generally comprise a support layer, one or more photosensitive layers, an optional slip film release layer, and an optional protective cover sheet. The protective cover sheet is formed from plastic or any other removable material that can protect the plate or photocurable element from damage until it is ready for use. The slip film may be disposed between the protective cover sheet and the photocurable layer(s) to protect the plate from contamination, increase ease of handling, and act as an ink-accepting layer. After exposure and development, the photopolymer flexographic printing plate consists of various image elements supported by a floor layer and anchored to a backing substrate. Flexographic printing elements can be manufactured in various ways including with sheet polymers and by the processing of liquid photopolymer resins.

Flexographic printing plates desirably work under a wide range of conditions. For example, they should be able to impart their relief image to a wide range of substrates, including cardboard, coated paper, newspaper, calendared paper, and polymeric films such as polypropylene, by way of example and not limitation. Importantly, the image should be transferred quickly and with fidelity, for as many prints as the printer desires to make.

The support sheet or backing layer lends support to the plate. The support sheet, or backing layer, can be formed from a transparent or opaque material such as paper, cellulose film, plastic, or metal. Preferred materials include sheets made from synthetic polymeric materials such as polyesters, polystyrene, polyolefins, polyamides, and the like. Generally, the most widely used support layer is a flexible film of polyethylene terephthalate. The support sheet may also include an adhesive layer for more secure attachment to the photocurable layer(s). Optionally, an antihalation layer may be provided between the support layer and the one or more photocurable layers to minimize halation caused by the scattering of UV light within the non-image areas of the photocurable resin layer.

The photocurable layer(s) can include any of the known photopolymers, monomers, initiators, reactive or non-reactive diluents, fillers, and dyes. The term “photocurable” refers to a composition which undergoes polymerization, cross-linking, or any other curing or hardening reaction in response to actinic radiation with the result that the unexposed portions of the material can be selectively separated and removed from the exposed (cured) portions to form a three-dimensional or relief pattern of cured material. Preferred photocurable materials include an elastomeric compound, an ethylenically unsaturated compound having at least one terminal ethylene group, and a photoinitiator. Exemplary photocurable materials are disclosed in European Patent Application Nos. 0 456 336 A2 and 0 640 878 A1 to Goss, et al., British Patent No. 1,366,769, U.S. Pat. No. 5,223,375 to Berrier, et al., U.S. Pat. No. 3,867,153 to MacLahan, U.S. Pat. No. 4,264,705 to Allen, U.S. Pat. Nos. 4,323,636, 4,323,637, 4,369,246, and 4,423,135 all to Chen, et al., U.S. Pat. No. 3,265,765 to Holden, et al., U.S. Pat. No. 4,320,188 to Heinz, et al., U.S. Pat. No. 4,427,759 to Gruetzmacher, et al., U.S. Pat. No. 4,622,088 to Min, and U.S. Pat. No. 5,135,827 to Bohm, et al., the subject matter of each of which is herein incorporated by reference in its entirety. More than one photocurable layer may be used.

The photocurable materials generally cross-link (cure) and harden through radical polymerization in at least some actinic wavelength region. As used herein, actinic radiation is radiation capable of effecting a chemical change in an exposed moiety in the materials of the photocurable layer. Actinic radiation includes, for example, amplified (e.g., laser) and non-amplified light, particularly in the UV and violet wavelength regions. One commonly used source of actinic radiation is a mercury arc lamp, although other sources are generally known to those skilled in the art.

The protective layer or slip film is a thin layer that protects the photosensitive printing blank from dust and increases its ease of handling.

In a conventional (“analog”) plate making process, the slip film is transparent to UV light. In this process, the printer peels the cover sheet off the printing plate blank and places a negative on top of the slip film layer. The plate and negative are then subjected to flood-exposure by UV light through the negative. The areas exposed to the light cure, or harden, and the unexposed areas are removed (developed) to create the relief image on the printing plate. Instead of a slip film, a matte layer may also be used to improve the ease of plate handling. The matte layer typically comprises fine particles (silica or similar) suspended in an aqueous binder solution. The matte layer is coated onto the photopolymer layer and then allowed to air dry. A negative is then placed on the matte layer for subsequent UV-flood exposure of the photocurable layer.

In a “digital” or “direct to plate” plate making process, a laser is guided by an image stored in an electronic data file, and is used to create an in situ negative in a digital (i.e., laser ablatable) masking layer, which is typically a slip film which has been modified to include a radiation opaque material. Portions of the laser ablatable layer are ablated by exposing the masking layer to laser radiation at a selected wavelength and power of the laser. Examples of laser ablatable layers are described, for example, in U.S. Pat. No. 5,925,500 to Yang, et al., and U.S. Pat. Nos. 5,262,275 and 6,238,837 to Fan, the subject matter of each of which is herein incorporated by reference in its entirety. The plate and the in situ negative are then subjected to flood exposure by actinic radiation (e.g., UV light) through the in situ negative.

After imaging, the photosensitive printing element is developed to remove the =polymerized portions of the layer of photocurable material and reveal the crosslinked relief image in the cured photosensitive printing element. Typical methods of development include washing with various solvents or water, often with a brush. Other possibilities for development include the use of an air knife or heat plus a blotter. The resulting surface has a relief pattern that reproduces the image to be printed and which typically includes both solid areas and patterned areas comprising a plurality of relief printing dots. After the relief image has been developed, the relief image printing element may be mounted on a press and printing commenced.

Photocurable resin compositions typically cure through radical polymerization, upon exposure to actinic radiation. However, the curing reaction can be inhibited by molecular oxygen, because the oxygen functions as a radical scavenger. It is therefore desirable for the dissolved oxygen to be removed from the resin composition before image-wise exposure so that the photocurable resin composition can be more rapidly and uniformly cured. One method of removing the dissolved oxygen from the resin composition involves laminating a barrier membrane to the photosensitive printing blank and various barrier membranes have been developed that are compatible with the photosensitive layer and that exhibit desirable properties in terms of handling, rigidity (or flexibility), strength and processability described for example in U.S. patent application Ser. No. 12/826,773 filed Jun. 30, 2010, the subject matter of which is herein incorporated by reference in its entirety.

In a related process, the relief image printing element can be prepared using direct write technology in which laser light is employed to directly and selectively image a photoresin that has previously been cured to create a relief printing element. One of the problems associated with direct write/laser engraving technology is that atmospheric oxygen inhibits the curing reaction at the surface, which results in poor curing in the outermost layer of photoresin.

An alternative process of making flexographic printing elements involves the use of liquid photopolymer resins. One of the advantages of making flexographic printing elements from liquid photopolymer resin is that the uncured resin can be reclaimed from the non-image areas of the printing elements and used to make additional printing plates. Liquid photopolymer resins have a further advantage as compared to sheet polymers in terms of flexibility to enable the production of any required plate gauge simply by changing the machine settings. The plates are typically formed by placing a layer of liquid photopolymerizable resin on a glass plate but separated from the glass plate by the substrate and/or the coverfilm. Actinic radiation, such as UV light, is directed against the resin layer through a negative. The result is that the liquid resin is selectively cross-linked and cured to form a printing image surface that mirrors the image on the negative. Upon exposure to actinic radiation, the liquid photopolymer resin polymerizes and changes from a liquid state to a solid state to form the raised relief image. After the process is complete, non-crosslinked liquid resin can be recovered from the printing plates to make further plates.

Various processes have been developed for producing printing plates from liquid photopolymer resins as described, for example, in U.S. Pat. No. 5,213,949 to Kojima et al., U.S. Pat. No. 5,813,342 to Strong et al. and U.S. Patent Publication No. 2008/0107908 to Long et al., the subject matter of each of which is herein incorporated by reference in its entirety.

After relief exposure, the uncured resin can be recovered. In a typical process, the uncured resin is physically removed from the plate in a reclamation step such that it can be reused to make further plates. In all areas not exposed to UV radiation, the resin remains liquid after exposure and can then be reclaimed. This reclamation step not only saves material costs of the photopolymer resin but also reduces the use and cost of developing chemistry and makes a lighter plate that is safer and easier to handle. Any residual traces of liquid resin remaining are then removed by nozzle washing or brush washing using a wash-out solution to obtain a washed-out plate, leaving behind the cured relief image. In liquid platemaking, resin recovery is an important factor relating to the production of photopolymerizable resin printing plates because the resins used to produce the plates are relatively expensive.

The cured regions are insoluble in the developer solution, and so after development a relief image formed of cured photopolymerizable resin is obtained. The cured resin is likewise insoluble in certain inks, and thus may be used in flexographic printing.

Thereafter, the cured printing plate may be subjected to various post exposure steps. For example, the plate may be completely immersed in water and exposed to actinic radiation such as UV light emitted from a light source to perform a complete curing of the entire plate and to increase plate strength. Finally, the plate may be dried by blowing hot air on the plate or by using an infrared heater.

While the reclamation step recycles the unexposed liquid photopolymer so that it may be reused in the process, the thin coverfilm is simply removed and discarded. These coverfilms typically comprise polyethylene terephthalate or a similar transparent material that have desirable properties including handling properties, transparency, adhesive characteristics and strength. However, these films are typically not biodegradable and thus do not break down in the environment after disposal. Thus, it would be desirable to develop a material for use as a coverfilm that has similar properties to polyethylene terephthalate in terms of handling, transparency, adhesive characteristics and strength but that is capable of degrading in the environment.

Similarly, when manufacturing flexographic printing elements from sheet polymers, the coversheet, backing layer and oxygen harrier membrane used therein are also typically made of polyethylene terephthalate or other similar materials having desirable properties in terms of handling, transparency, flexibility, adhesive characteristics and strength and it would be desirable to utilize a material for these layers that has similar properties to polyethylene terephthalate in terms of handling properties, transparency, adhesive characteristics and strength but that degrades in the environment.

Polyethylene terephthalate and other synthetic polymer compounds are widely used due to their superior characteristics in terms of handling properties, rigidity (or flexibility), strength and processability. However, with the increase in the consumption of such synthetic polymer compounds however, the amount of waste has also been increasing as has the issue of disposing of such waste. Thus, there has been increased interest in developing biodegradable plastics that are usable in manufacturing relief image printing elements and that are capable of decomposing in the natural environment after disposal.

While biodegradable polymers have been developed for use as packaging materials and in surgical and other medical applications, to date they have not been used in the manufacture of printing plates. Known biodegradable plastics include starch-based plastics, aliphatic-polyester resins produced by microorganisms, chemically synthetic aliphatic polyester resins, including those that are partially modified in their chemical structure and biodegradable aliphatic aromatic polyester resins.

### SUMMARY OF THE INVENTION

It is an object of the present invention to improve the sustainability of a liquid flexographic platemaking process.

It is another object of the present invention to incorporate a biodegradable or compostable film into a liquid flexographic platemaking process.

It is still another object of the present invention to utilize a biodegradable film for use as an oxygen barrier membrane in direct write/laser engravable printing plates.

It is still another object of the present invention to utilize a biodegradable film as a coverfilm, slip film, oxygen barrier membrane, or substrate layer in a digitally imagable flexographic printing plate.

It is still another object of the present invention to provide a biodegradable film for use as an oxygen barrier membrane in a digital plate making process.

To that end, in a preferred embodiment, the present invention relates generally to relief image printing plates produced using curable liquid photopolymer resins, laser engravable photoresins and photocurable sheet polymers and methods of manufacturing the same in which biodegradable polymer films may be used as substrate layers, coverfilms and oxygen barrier membranes in the production thereof. Thus, once the relief image printing plate has been used and disposed of, the biodegradable polymer films are capable of decomposing in the environment.

### DETAILED DESCRIPTION OF THE PREFERRED EMBODIMENTS

As used herein, the term “degradable” or “biodegradable” refers to a polymer having a polymer molecular structure which can decompose to smaller molecules in the natural environment over a reasonable period of time. As described herein, the degradable polymer can be hydrolytically degradable wherein water reacts with the polymer to form two or more molecules from the polymer. The polymer may be further characterized as being degradable within a time frame in which products made from the materials, after use, can either be recycled by decomposition of the polymer into its monomeric units or, if disposed of in the environment (e.g., a landfill), the polymer degrades quickly enough to avoid significant accumulation of discarded products or the rate of accumulation is significantly less than that of similar products that are not degradable. Degradable polymers are distinct from nondegradable polymers in that over time the molecular structure breaks down, allowing the polymer to slowly disintegrate or degrade.

“Biodegradation” refers to a compound that is subject to decomposition by microorganisms. For example, a polymer such as polylactic acid can be degraded by hydrolysis to individual lactic acid molecules which are subject to biological decomposition by a wide variety of microorganisms. This biodegradation should occur in the outdoors environment.

The present invention relates generally to a biodegradable aliphatic polyester film having desirable handling properties, transparency and adhesive characteristics for use in the manufacture of flexographic relief image printing plates. In a preferred embodiment, the aliphatic polyester is a polylactic acid resin that has suitable characteristics in terms of handling properties, strength, rigidity (or flexibility), transparency and adhesive characteristics for its use in the manufacture of flexographic relief image printing plates.

Polylactic acid polymers are derived from agricultural by-products such as corn starch or other starch-rich substances like maize, sugar or wheat and are produced by preparing lactic acid typically from a starch derived from corn or potatoes and subjecting the lactic acid to chemical synthesis. While polylactic acid polymers have been used in various packaging and other applications, as discussed above, it has not previously been contemplated to use such biodegradable polymers in the production of relief image printing elements.

Polylactic acid polymer compositions are typically stretched in at least one axial direction to form the plastic and subjected to thermal treatment. Stretching the formed plastic orients and crystallizes the matrix polylactic acid polymer and improves physical properties in the strength of the formed plastic due to orientation and crystallization and thereby yielding formed plastics having both the desired flexibility and the desired strength.

In addition, various strategies can be employed for controlling the rate of degradation of the biodegradable materials described herein. For example, one strategy for controlling degradation of materials is to change the molecular weight of the polymer. Higher molecular weight materials will degrade more slowly because each polymeric molecule requires more hydrolytic reactions for total degradation. Higher molecular weights of polylactic acid can be achieved, for example, by polymerizing lactide rather than direct polymerization of lactic acid. In addition, cross-linking of polymers achieves effective higher molecular weights and more tightly bound materials which degrade at a slower rate.

Another mechanism for controlling the degradation of the biodegradable materials is to change the hydrophilic or hydrophobic nature of the material. The degradation rate of a polymer that is hydrolytically degradable can be reduced by making the material more hydrophobic so that water penetration of the material will be retarded. In addition, the hydrophobic or hydrophilic nature of the material can be modified by physically blending in compounds that are either hydrophobic or hydrophilic to the material without being chemically bound to any of the constituents.

Another mechanism for controlling the degradation of materials is to vary the crystalline structure of the polymer in the materials. For polymers which are more crystalline and ordered in their molecular structure, the ability of water to infiltrate and hydrolytically degrade polymers is reduced. Thus, by producing materials that are less crystalline in structure, the rate of degradation can be increased. For example, the incorporation of modifiers, such as plasticizers, into the polymer will reduce the crystalline nature of the material.

In a preferred embodiment, the present invention relates generally to a liquid developable relief image printing plate comprising:

a biodegradable coverfilm having a liquid photopolymer resin layer cast thereon;

wherein the liquid photopolymer resin layer is selectively crosslinked and cured through a negative to form a printing image surface that mirrors the image on the negative,

wherein non-crosslinked and cured liquid photopolymer resin can be reclaimed and reused; and

wherein once the relief image printing plate has been used and disposed of, the biodegradable coverfilm is capable of decomposing in the environment.

In a preferred embodiment, the biodegradable coverfilm comprises an aliphatic polyester film such as a polylactic acid polymer. Other biodegradable aliphatic polyester films having similar properties to polylactic acid and/or similar desirable properties in terms of handling, transparency, adhesive characteristics, flexibility, strength and other desirable properties are also usable in the present invention.

The biodegradable coverfilm preferably has a thickness of between about 15 microns and about 50 microns, more preferably a thickness of between about 15 and about 30 microns. Of course, the thickness of the biodegradable coverfilm depends in part on the overall thickness of the printing plate as well as the particular purpose of the film.

In a preferred embodiment, the biodegradable coverfilm preferably has a tensile strength in the range of about 7,500 psi to about 8,500 psi in both a machine and a transverse direction. The biodegradable coverfilm also preferably exhibits a shrinkage of less than about 10%, and a glass transition temperature of between about 120 and about 180.

In addition, the biodegradable coverfilm preferably has a moisture vapor transmission rate of between about 5 and about 35 grams/100 in²/24 hours, which typically varies inversely to the thickness of the biodegradable film. Therefore the use of a film with a desired moisture vapor transmission rate may require a film having a different thickness.

In another preferred embodiment, the present invention relates generally to a method of making a liquid developable relief image printing element comprising the steps of:

a) casting a layer of liquid photopolymer resin onto a biodegradable coverfilm;

b) placing a negative of a desired age on the layer of liquid photopolymer resin;

c) selectively crosslinking and curing the layer of liquid photopolymer resin through the negative to form a printing image surface that mirrors the image on the negative; and

d) reclaiming uncured liquid photopolymer resin remaining after the layer of liquid photopolymer resin has been selectively crosslinked and cured;

wherein once the relief image printing plate has been used and disposed of, the biodegradable coverfilm is capable of decomposing in the environment.

In another preferred embodiment, the present invention relates generally to a laser engravable relief image printing plate comprising:

a) a support layer;

b) at least one layer of photoresin on the support layer; and

c) a removable coversheet on the at least one layer of photoresin,

wherein at least one of the support layer and the removable coversheet comprises a biodegradable polymer film, wherein after the printing plate is used and disposed of, the biodegradable polymer is capable of decomposing in the environment.

In this instance, the laser engravable relief image printing plate is imaged to create a relief image therein by imaging the at least one layer of photoresin to create a relief image therein, preferably using a laser. Thus, it is important that the coversheet be transparent to actinic radiation so that the printing element can be imaged through the cover sheet.

The thickness of the coversheet should be consistent with the structural needs for handling of the film and the film/photopolymer plate combination, and thicknesses between about 5 and 300 microns are preferred, with thickness of between about 10 and about 200 microns being most preferred.

In still another preferred embodiment, the present invention relates generally to photocurable relief image printing plate comprising:

a) a support layer;

b) at least one photocurable resin layer deposited on the support layer;

c) a laser ablatable masking layer;

d) optionally, a removable or developable oxygen barrier membrane; and

wherein at least one of the support layer, the oxygen barrier membrane, and the removable coversheet comprises a biodegradable polymer film, wherein after printing plate is used and disposed of, the biodegradable polymer film is capable of decomposing in the environment. In this regard, the cover sheet itself can act as the oxygen barrier membrane or a separate membrane can be applied. The cover sheet is generally removed before ablating the mask layer and if used the oxygen barrier membrane is generally applied after ablation but before exposure to U.V. radiation.

It is noted that if used, either the laser ablatable masking layer or the oxygen barrier membrane may be disposed directly on the at least one photocurable layer and the other of the two layers then disposed on top depending on the needs of the customer, as described, for example in U.S. patent application Ser. No. 12/826,773 filed Jun. 30, 2010, the subject matter of which is herein incorporated by reference in its entirety.

In one embodiment, the biodegradable polymer comprises an aliphatic polyester film and more preferably comprises a polylactic acid polymer.

It is noted that the thickness of the biodegradable film depends in part on the overall thickness of the printing plate as well as the particular purpose of the film. For example, it is envisioned that the use of the biodegradable film as a substrate layer will require a film with a greater thickness than the use of the biodegradable film as a coverfilm or as an oxygen barrier membrane. For example, when used as a coverfilm, the biodegradable polymer film preferably has a thickness of between about 15 microns and about 50 microns, more preferably a thickness of between about 15 and about 30 microns. When used as an oxygen barrier membrane, the biodegradable polymer film preferably has a thickness between about 20 mils and about 40 microns, more preferably between about 20 and about 30. Finally, when used as a substrate layer, the biodegradable film preferably has a thickness between about 3 mils and about 12 mils, more preferably between about 4 and about 10. Of course, other uses of the biodegradable film in photosensitive printing plate production may require other thicknesses of the biodegradable film.

The biodegradable polymer coverfilm also preferably has a tensile strength in the range of about 7,500 psi to about 8,500 psi, more preferably about 8,000 psi in both a machine and a transverse direction.

The film typically has a shrinkage of less than about 10% and a glass transition temperature of between about 120 and about 180.

The biodegradable polymer film also preferably has a moisture vapor transmission rate of between about 5 and about 35 grams/100 in²/24 hours, which typically varies inversely to the thickness of the biodegradable film. In addition, the biodegradable polymer film also preferably has an oxygen permeation of between about 25 and about 75 cm³/100 in²/24 hours, which also typically varies inversely to the thickness of the biodegradable film. Therefore, if a particular moisture vapor transmission rate or oxygen permeation is necessary such as in applications where the biodegradable polymer film is being used as an oxygen barrier membrane, a particular thickness of film is necessary to achieve these properties. Thus, for example, in one embodiment, the thickness of the film is between about 15 and about 50 microns and the oxygen permeation is between about 70 and about 35 cm³/100 in²/24 hours and the moisture vapor transmission rate is between about 32 and about 19 grams/100 in²/24 hours.

In another preferred embodiment, the present invention also relates generally to a method of making a photosensitive relief image printing element comprising the steps of:
a) disposing at least one photocurable layer on a support layer;
b) disposing a laser ablatable mask layer on the at least one photocurable layer;
c) laser ablating the laser ablatable mask layer to create an in situ negative in the laser ablatable layer;
d) optionally, disposing an oxygen barrier membrane on the at least one photocurable layer;
e) selectively crosslinking and curing the at least one photocurable layer through the in situ negative to form a printing image surface;

wherein at least one of the support layer, an oxygen barrier membrane comprises a biodegradable polymer film; and

wherein once the relief image printing plate has been used and disposed of, the biodegradable polymer film is capable of decomposing in the environment. If a removable cover sheet is also used, it is preferably comprised of a biodegradable polymer film.

Various polylactic acid films and other similar materials are usable in the practice of the present invention so long as they exhibit the desired properties. In one embodiment the polylactic acid film comprises EarthFirst® BCP, available from Plastic Suppliers, Inc., which is a biaxially oriented blow clear packaging film which has properties set forth in Table 1:

TABLE 1
Properties of EarthFirst ® BCP

| | | | | | | | | Test |
|---|---|---|---|---|---|---|---|---|
| Physical | | | | | | | | Method |
| property | Units | Typical Value | | | | | | (ASTM) |
| Thickness | mil | 0.80 | 1.00 | 1.20 | 1.60 | 2.00 | 3.00 | D4321 |
| | gauge | 80 | 100 | 120 | 160 | 200 | 300 | |
| Yield | in²/lb | 27,680 | 22,144 | 18,453 | 13,840 | 11,072 | 7,381 | D4321 |
| Gloss (60°) | G.U. | 125 | | | | | | D523 |
| Haze | % | 4.0 | 4.0 | 4.7 | 5.4 | 7.0 | 15.0 | D1003 |
| Surface tension | Dynes/ | 38 | | | | | | D5946 |
| untreated surface | cm | | | | | | | |
| Coeff. of friction | | 0.55 | | | | | | D1894 |
| film to film | | | | | | | | |
| MVTR | gm/100 in²/ | 32 | 23 | 19 | 14 | 10 | 8 | 100° F., |
| | 24 h | | | | | | | 100% RH |
| O₂ TR | cc/100 in²/ | 70 | 47 | 36 | 33 | 29 | 27 | 73.4° F., |
| | 24 h | | | | | | | 0% RH |

| | | | |
|---|---|---|---|
| Ultimate tensile | psi | | |
| strength | | | |
| MD | | 8,000 | D882 |
| TD | | 8,000 | |
| Compostable | | Passed | D6400 |

In addition, other biodegradable films having similar properties to EarthFirst® BCP are also usable in the present invention.

Thus, it can be seen that biodegradable films can be used in the manufacture of relief image printing plates to provide a product that is more capable of degrading in the environment.

What is claimed is:

1. A liquid developable relief image printing plate comprising:
a biodegradable coverfilm having a liquid photopolymer resin layer cast thereon;
wherein the liquid photopolymer resin layer is selectively crosslinked and cured through a negative to form a printing image surface that mirrors the image on the negative,
wherein non-crosslinked and cured liquid photopolymer resin can be reclaimed and reused; and
wherein once the relief image printing plate has been used and disposed of, the biodegradable coverfilm is capable of decomposing in the outdoors environment.

2. The liquid developable relief image printing element according to claim 1, wherein the biodegradable coverfilm comprises an aliphatic polyester film.

3. The liquid developable relief image printing element according to claim 2, wherein the biodegradable coverfilm comprises a polylactic acid polymer.

4. The liquid developable relief image printing element according to claim 1, wherein the biodegradable film has a thickness of between about 15 microns and about 50 microns.

5. The liquid developable relief image printing element according to claim 2, wherein the biodegradable coverfilm has a tensile strength in the range of about 7,500 psi to about 8,500 psi in both a machine and a transverse direction.

6. The liquid developable relief image printing element according to claim 4, wherein the biodegradable coverfilm has a moisture vapor transmission rate of between about 5 and about 35 grams/100 in²/24 hours.

7. The liquid developable relief image printing element according to claim 6, wherein the moisture vapor transmission rate varies inversely to the thickness of the biodegradable film.

8. A method of making a liquid developable relief image printing element comprising the steps of:
a) casting a layer of liquid photopolymer resin onto a biodegradable coverfilm;
b) placing a negative of a desired image on the layer of liquid photopolymer resin;
c) selectively crosslinking and curing the layer of liquid photopolymer resin through the negative to form a printing image surface that mirrors the image on the negative; and
d) reclaiming uncured liquid photopolymer resin remaining after the layer of liquid photopolymer resin has been selectively crosslinked and cured;
wherein once the relief image printing plate has been used and disposed of, the biodegradable coverfilm is capable of decomposing in the outdoors environment.

9. The method according to claim 8, wherein the biodegradable coverfilm comprises an aliphatic polyester film.

10. The method according to claim 9, wherein the biodegradable coverfilm comprises a polylactic acid polymer.

11. The method according to claim 9, wherein the biodegradable film has a thickness of between about 15 and about 50 microns.

12. The method according to claim 8, wherein the biodegradable coverfilm has a tensile strength in the range of about 7,500 psi to about 8,500 psi in both a machine and a transverse direction.

13. The method according to claim 11, wherein the biodegradable coverfilm has a moisture vapor transmission rate of between about 5 and about 35 grams/100 in²/24 hours.

14. The method according to claim 13, wherein the moisture vapor transmission rate varies inversely to the thickness of the biodegradable film.

15. A laser engravable relief image printing plate comprising:
a) a support layer;
b) at least one layer of photoresin on the support layer; and
c) a removable coversheet on the at least one layer of photoresin,
wherein at least one of the support layer and the removable coversheet comprises a biodegradable polymer film, wherein after printing plate is used and disposed of, the biodegradable polymer is capable of decomposing in the outdoors environment.

16. The laser engravable relief image printing plate according to claim 15, wherein the biodegradable polymer film comprises an aliphatic polyester film.

17. The laser engravable relief image printing plate according to claim 16, wherein the biodegradable polymer film comprises a polylactic acid polymer.

18. The laser engravable relief image printing plate according to claim 15, wherein the biodegradable polymer film has a thickness of between about 15 and about 50 microns.

19. The photosensitive relief image printing plate according to claim 18, wherein the biodegradable polymer film has a moisture vapor transmission rate of between about 5 and about 35 grams/100 in²/24 hours.

20. The photosensitive relief image printing plate according to claim 19, wherein the moisture vapor transmission rate varies inversely to the thickness of the biodegradable polymer film.

21. A photocurable relief image printing plate comprising:
a) a support layer;
b) at least one photocurable resin layer deposited on the support layer;
c) a laser ablatable masking layer;
d) optionally, a removable or developable oxygen barrier membrane; and
e) a removable coversheet;
wherein at least one of the support layer, the oxygen bather membrane, and the removable coversheet comprises a biodegradable polymer film, wherein after printing plate is used and disposed of, the biodegradable polymer film is capable of decomposing in the outdoors environment.

22. The photocurable relief image printing plate according to claim 21, wherein the biodegradable polymer film comprises an aliphatic polyester film.

23. The photocurable relief image printing plate according to claim 22, wherein the biodegradable polymer film comprises a polylactic acid polymer film.

24. The photocurable relief image printing plate according to claim 21, wherein the biodegradable polymer film has a thickness of between about 15 mils and about 50 microns.

25. The photocurable relief image printing plate according to claim 21, wherein the biodegradable film has a tensile strength in the range of about 7,500 psi to about 8,500 psi in both a machine and a transverse direction.

26. The photocurable relief image printing plate according to claim 22, wherein the biodegradable polymer film has a moisture vapor transmission rate of between about 5 and about 35 grams/100 in²/24 hours.

27. The photocurable relief image printing plate according to claim 26, wherein the moisture vapor transmission rate varies inversely to the thickness of the biodegradable polymer film.

28. The photocurable relief image printing plate according to claim 24, wherein the oxygen barrier membrane comprises a biodegradable polymer film and the oxygen permeation of the biodegradable polymer film is between about 25 and about 75 cm³/100 in²/24 hours.

29. The photocurable relief image printing plate according to claim 28, wherein the oxygen permeation of the biodegradable polymer film varies inversely to its thickness, and wherein the thickness of the film is between about 20 and about 40 microns and the oxygen permeation is between about 70 and about 35 cm³/100 in²/24 hours.

30. A method of making a photosensitive relief image printing element comprising the steps of:
a) disposing at least one photocurable layer on a support layer;
b) disposing a laser ablatable mask layer on the at least one photocurable layer;
c) laser ablating the laser ablatable mask layer to create an in situ negative in the laser ablatable layer;
d) optionally, disposing an oxygen barrier membrane on the at least one photocurable layer;
e) selectively crosslinking and curing the at least one photocurable layer through the in situ negative to form a printing image surface;
wherein at least one of the support layer, and the oxygen barrier membrane and comprises a biodegradable polymer film; and
wherein once the relief image printing plate has been used and disposed of the biodegradable polymer film is capable of decomposing in the outdoors environment.

31. The method according to claim 30, wherein the biodegradable polymer film comprises an aliphatic polyester film.

32. The method according to claim 31, wherein the biodegradable polymer film comprises a polylactic acid polymer.

33. The method according to claim 31, wherein the biodegradable polymer film has a thickness of between about 15 and about 50 microns.

34. The method according to claim 31, wherein the biodegradable polymer film has a tensile strength in the range of about 7,500 psi to about 8,500 psi in both a machine and a transverse direction.

35. The method according to claim 33, wherein the biodegradable polymer film has a moisture vapor transmission rate of between about of between about 5 and about 35 grams/100 in²/24 hours.

36. The method according to claim 35, wherein the moisture vapor transmission rate varies inversely to the thickness of the biodegradable polymer film.

37. The method according to claim 33, wherein the oxygen barrier membrane comprises a biodegradable polymer film and the oxygen permeation of the biodegradable polymer film is between about 25 and about 75 cm³/100 in²/24 hours.

38. The method according to claim 37, wherein the oxygen permeation of the biodegradable polymer film varies inversely to its thickness, and wherein the thickness of the biodegradable polymer film is between about 20 and about 40 microns and the oxygen permeation is between about 70 and about 35 cm³/100 in²/24 hours.
